(19) United States
(12) Patent Application Publication
(10) Pub. No.: US 2015/0072445 A1
(43) Pub. Date: Mar. 12, 2015

(54) LITHOGRAPHY APPARATUS AND METHOD OF MANUFACTURING ARTICLE

(71) Applicant: CANON KABUSHIKI KAISHA, Tokyo (JP)

(72) Inventors: Toshiro Yamanaka, Yokohama-shi (JP); Gaku Takahashi, Utsunomiya-shi (JP); Go Tsuchiya, Tochigi-shi (JP); Shinji Ohishi, Oyama-shi (JP)

(21) Appl. No.: 14/481,088

(22) Filed: Sep. 9, 2014

(30) Foreign Application Priority Data
Sep. 10, 2013 (JP) 2013-187646

(51) Int. Cl. H01J 37/317; H01L 21/66; H01J 37/304; H01L 21/3065; H01J 37/20; H01J 37/02

(52) U.S. Cl. CPC H01J 37/3177; H01J 37/20; H01J 37/023; H01J 37/3045; H01L 21/3065; H01L 22/26; H01J 2237/20285; H01J 2237/201; H01J 2237/18; H01J 2237/20228
USPC 438/7; 250/492.22

(57) ABSTRACT

A lithography apparatus which performs writing on a substrate using a charged particle beam is provided. The apparatus comprises a plurality of column units each of which comprises a charged particle optical system, a plurality of stages each of which is movable while holding the substrate, and a controller. The controller moves the stages in synchronization with each other in a positional relationship corresponding to an arrangement of the column units, and performs writing on substrates held in the stages simultaneously.

### BACKGROUND OF THE INVENTION

1. Field of the Invention

The present invention relates to a lithography apparatus and a method of manufacturing an article.

2. Description of the Related Art

In the manufacture of a semiconductor device, the need for refining the line width is becoming stricter year by year. One of production apparatuses which obtains a resolution with a line width of 10 nm or less is an electron beam lithography apparatus. In particular, a multi-electron beam lithography apparatus which writes patterns simultaneously with a plurality of electron beams without using any mask has been proposed (Japanese Patent Laid-Open No. 2011-513905). The multi-electron beam lithography apparatus has many advantages, toward practical applications, that it eliminates the need for a mask which is one factor of manufacturing cost, and it can control each electron beam in a programmable manner and is, thus suitable for manufacturing a variety of devices in small quantities, and the like.

In general, however, the electron beam lithography takes writing time about ten times or more for the same field size as compared to optical lithography and is thus poor in a throughput. To cope with this, Japanese Patent Laid-Open No. 2012-518902 discloses an arrangement which improves a throughput by arranging a plurality of clusters each of which is comprised of an electron beam lithography apparatus.

A conventional cluster type electron beam lithography apparatus has one chamber in one cluster, and includes, inside the chamber, one substrate moving stage and one electron beam column unit. Accordingly, the cluster type electron beam lithography apparatus processes one substrate per cluster. Since a space where an actuator of a moving stage is arranged and a space for a chamber wall are redundant, substrate processing throughput efficiency per footprint is poor even if clustering is performed.

### SUMMARY OF THE INVENTION

The present invention provides, for example, a lithography apparatus which improves a substrate processing throughput per footprint.

According to one aspect of the present invention, a lithography apparatus which performs writing on a substrate using a charged particle beam, comprises a plurality of column units each of which comprises a charged particle optical system, a plurality of stages each of which is movable while holding the substrate, and a controller configured to move the plurality of stages in synchronization with each other in a positional relationship corresponding to an arrangement of the plurality of column units, and perform writing on a plurality of substrates held in the plurality of stages simultaneously.

Further features of the present invention will become apparent from the following description of exemplary embodiments (with reference to the attached drawings).

### BRIEF DESCRIPTION OF THE DRAWINGS

FIG. 1 is a view showing the arrangement of a lithography apparatus according to the first embodiment;

FIG. 2 is a view showing the arrangement of a lithography apparatus according to the second embodiment;

FIG. 3 is a view showing the arrangement of a lithography apparatus according to the third embodiment;

FIG. 4 is a view showing the arrangement of a lithography apparatus according to a modification of the third embodiment;

FIG. 5 is a view showing the arrangement of a lithography apparatus according to the fourth embodiment;

FIG. 6 is a view showing the arrangement of a lithography apparatus according to the fifth embodiment;

FIG. 7 is a view showing the arrangement of a lithography apparatus according to the sixth embodiment;

FIG. 8 is a view showing the arrangement of a lithography apparatus according to the seventh embodiment; and

FIG. 9 is a view showing the arrangement of a lithography apparatus according to the eighth embodiment.

### DESCRIPTION OF THE EMBODIMENTS

Various exemplary embodiments, features, and aspects of the invention will be described in detail below with reference to the drawings.

Preferred embodiments of the present invention will be described in detail below with reference to the accompanying drawings. Note that the following embodiments are not intended to limit the present invention and are merely concrete examples advantageous in practicing the invention. Also, not all combinations of features to be described in the embodiments are indispensable for the means to solve the problems according to the present invention.

### First Embodiment

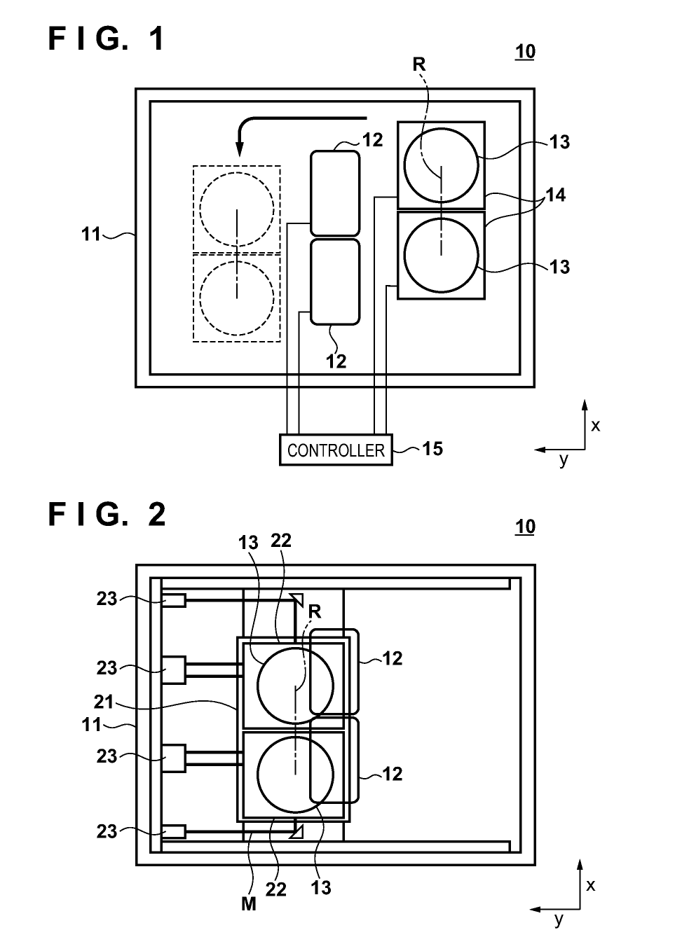

FIG. 1 is a plan view showing the arrangement of a lithography apparatus according to the first embodiment. A lithography apparatus 10 according to this embodiment is, for example, a writing apparatus which performs writing on a substrate using a charged particle beam. The substrate is, for example, a silicon wafer or a glass substrate. The lithography apparatus 10 has a vacuum chamber 11. A plurality of column units each of which comprises a charged particle optical system are located inside this vacuum chamber 11. In this embodiment, for example, two column units 12 are arranged. In addition, a plurality of stages movable in the x and y directions while holding substrates 13 are located in the vacuum chamber 11. In this embodiment, for example, two stages 14 are located. A controller 15 performs control of the charged particle optical systems in the column units 12 and control of respective components including the stages 14.

The vacuum chamber 11 is necessary to maintain stability of charged particles till they are irradiated after they were generated. Each column unit 12 is contained and fixed in the vacuum chamber 11, and can irradiate a predetermined position with the charged particles. In this embodiment, the plurality of column units are arranged to process a plurality of substrates simultaneously and in parallel. Furthermore, it is desirable that charged particle columns inside the column units can irradiate the position with as many charged particles as possible at once. Hence, it is desirable that one column unit includes a plurality of columns each of which includes a charged particle optical system comprised of an electron gun, lenses, deflectors, and the like, so that a number of electron beams can be irradiated simultaneously. The concrete examples thereof will be described later in the fourth and the fifth embodiments.

Irradiation positions need to be changed to irradiate the entire surfaces of the substrates. This function can be implemented by positioning the substrates directly under the corresponding column units by the corresponding stages. In this embodiment, in particular, the column units are used for the respective substrates, and the plurality of column units are fixed. The controller 15 causes the stages 14 to move while keeping the relative distance (indicated by an alternate long and short dashed line R in FIG. 1) of the substrates 13 almost constant. This allows the plurality of stages 14 to move in synchronization with each other in a positional relationship corresponding to the arrangement of the plurality of column units 12. This makes it possible to perform writing on the substrates 13 held in the stages 14 simultaneously and in parallel. As a consequence, the moving distance of each substrate and the relative distance between the plurality of substrates can be minimized within the necessary range, thereby improving a substrate processing throughput per footprint.

### Second Embodiment

A lithography apparatus according to the second embodiment will now be described with reference to FIG. 2. In the present invention, a plurality of substrates are processed simultaneously, thus requiring high overlay accuracy for all the substrates equally. In order to meet the requirement, the apparatus according to this embodiment measures the positions of all the substrates or the positions of substrate holders of all stages by a measurement unit arranged in a predetermined position. This arrangement makes it possible to accurately measure irradiation positional errors from target values for all the substrates. Furthermore, each column unit can control a beam position. Beam position control is possible by, for example, a deflector or a pattern (a pattern data) change. If the irradiation positional error falls within the range of this beam position control, it can be corrected by beam position control based on the measurement value of the error.

FIG. 2 shows an example in which two substrates are processed simultaneously. In this embodiment, two fine moving stages 22 are mounted on a coarse moving stage 21 which is movable in the x and y directions. Substrates 13 are held on the respective fine moving stages. Each laser interferometer 23 which serves as a measurement unit fixed in a predetermined position of a vacuum chamber 11 can measure the side position of each fine moving stage by the reflected light from measurement light M, and measure the translation positions x and y, and an angle θz about a z-axis of each substrate. Note that in FIG. 2, column units 12, the coarse moving stage 21, the fine moving stages 22, and the laser interferometers 23 can be controlled by a controller 15 as in the first embodiment, and the illustration thereof is omitted (the same shall apply hereinafter).

A position measurement principle is based not only on the laser interferometer but also on a laser displacement sensor, a capacitive sensor, an encoder, a magnetostrictive sensor or a combination thereof.

### Third Embodiment

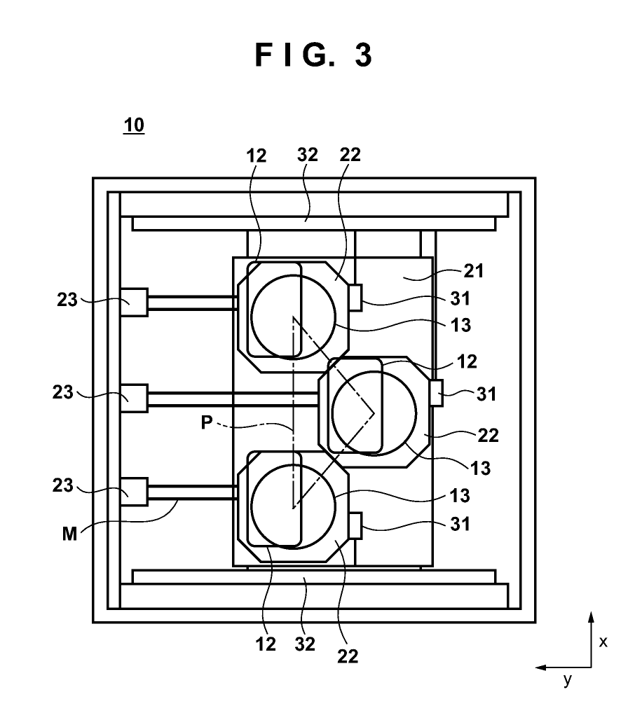

A lithography apparatus according to the third embodiment will now be described with reference to FIG. 3. In this embodiment, a plurality of column units are arranged so that two or less column units are arranged on the same line in a planar view. This arrangement makes it possible to measure a position in the x and y directions from a fixed position for each substrate even in an arrangement where three or more substrates are handled. Footprint efficiency can also be improved.

In the example of FIG. 3, three column units 12 are arranged at the respective vertex positions of a triangle in the planar view. An alternate long and short dashed line P in FIG. 3 represents this triangle. Three fine moving stages 22 are arranged on a coarse moving stage 21 in positions corresponding to this column unit arrangement. This makes it possible to move the plurality of fine moving stages in synchronization with each other in a positional relationship corresponding to the column unit arrangement, and perform writing on substrates 13 held in the respective fine moving stages simultaneously.

The position y and the rotation θz of each fine moving stage can be measured by each laser interferometer 23 fixed to a vacuum chamber 11. Furthermore, a laser interferometer 31 fixed to each fine moving stage measures bar mirrors 32 fixed to the vacuum chamber 11. This makes it possible to measure a position x of each fine moving stage.

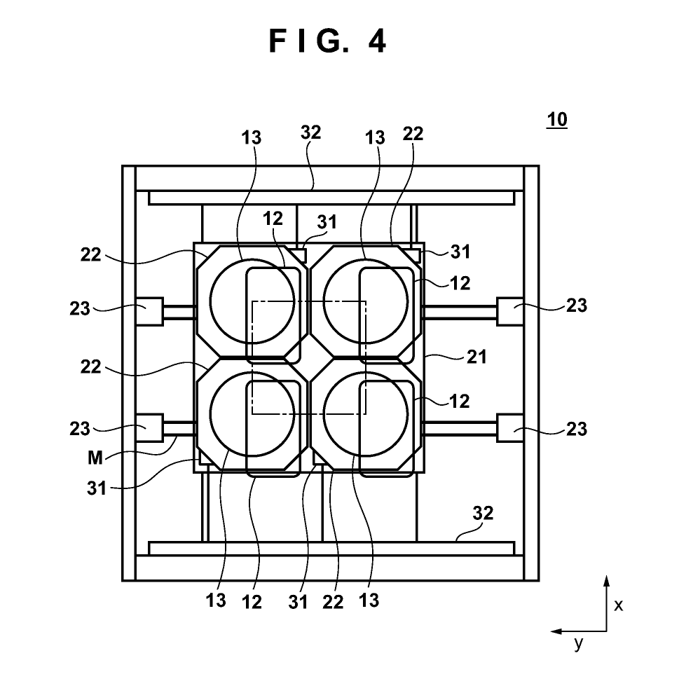

In the example of FIG. 4, four column units 12 are arranged at the respective vertex positions of a rectangle in the planar view. An alternate long and short dashed line in FIG. 4 represents this rectangle. Four fine moving stages 22 are arranged on the coarse moving stage 21 in positions corresponding to this column unit arrangement. This makes it possible to move the plurality of fine moving stages in synchronization with each other in a positional relationship corresponding to the column unit arrangement, and perform writing on the substrates 13 held in the respective fine moving stages simultaneously.

The position y and the rotation θz of each fine moving stage can be measured by each laser interferometer 23 fixed to the vacuum chamber 11. Furthermore, the laser interferometer 31 fixed to each fine moving stage measures the bar mirrors 32 fixed to the vacuum chamber 11. This makes it possible to measure the position x of each fine moving stage.

### Fourth Embodiment

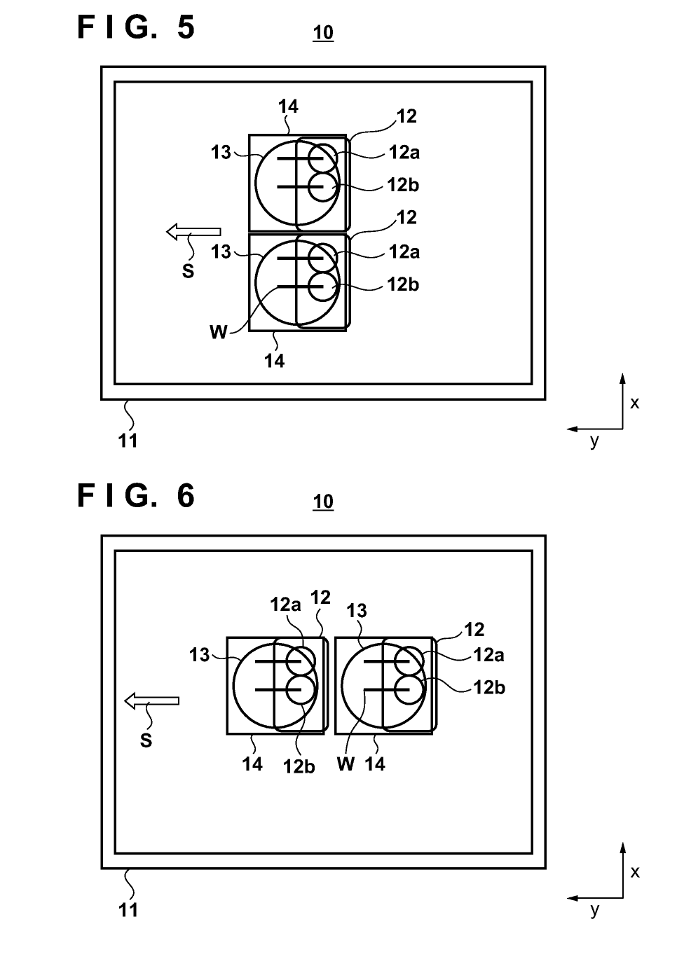

A lithography apparatus according to the fourth embodiment will now be described with reference to FIG. 5. In this embodiment, each column unit includes a plurality of columns. Each column includes a charged particle optical system comprised of an electron gun, lenses, deflectors, and the like. A controller 15 controls electron beams from the respective columns independently. This makes it possible to irradiate one substrate with the plurality of electron beams. In the example of FIG. 5, each column unit 12 includes two columns 12a and 12b. The arrayed direction of the columns 12a and 12b is parallel to that of two column units. More specifically, two column units are arranged in the x-axis direction, and two columns within each column unit are also arranged in the x-axis direction. At this time, scanning for writing is performed in the y-axis direction. As shown in FIG. 5, stripe-shaped patterns W are transferred to substrates 13, and then two substrates are moved step by step in the x direction to transfer next patterns to the substrate. By repeating these steps, the patterns can be transferred to the entire surfaces of the substrates. A scanning direction S for writing is defined by a column array. Therefore, setting the column array and a substrate array to be parallel to each other eliminates a wasteful moving distance. This makes it possible to minimize a relative distance between the substrates. This embodiment is advantageous in a mode in which the arrayed direction of the columns is oblique to the arrayed direction of the column units (that is, the arrayed direction of the substrates).

### Fifth Embodiment

A lithography apparatus according to the fifth embodiment will now be described with reference to FIG. 6. In the example of FIG. 6, each column unit 12 includes two columns 12a and 12b. The arrayed direction of the columns 12a and 12b is perpendicular to that of two column units. More specifically, while two column units are arranged in the y-axis direction, two columns within each column unit are arranged in the x-axis direction. At this time, scanning for writing is performed in the y-axis direction. As shown in FIG. 6, stripe-shaped patterns W are transferred to substrates 13, and then two substrates are moved step by step in the x direction to transfer next patterns to the substrate. By repeating these steps, the patterns can be transferred to the entire surfaces of the substrates. Also in this way, a relative distance between the substrates can be minimized. This embodiment is also advantageous in a mode in which the arrayed direction of the columns is oblique to the arrayed direction of the column units (that is, the arrayed direction of the substrates).

### Sixth Embodiment

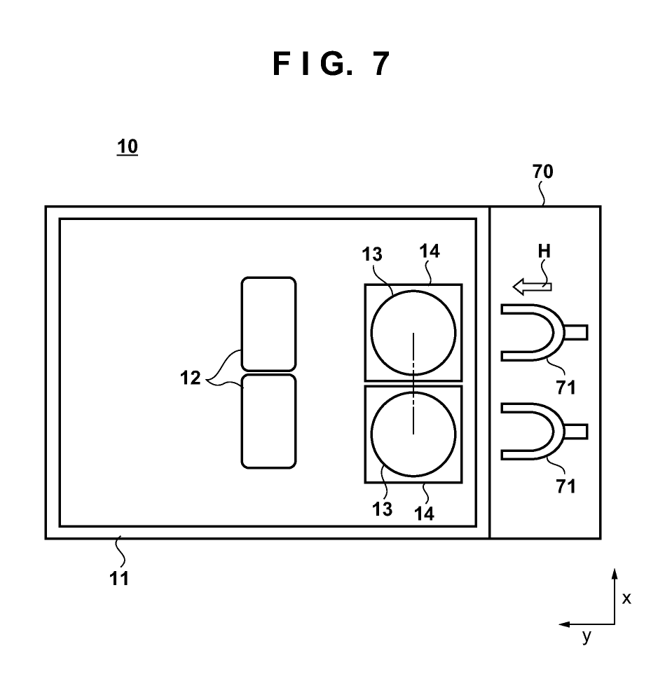

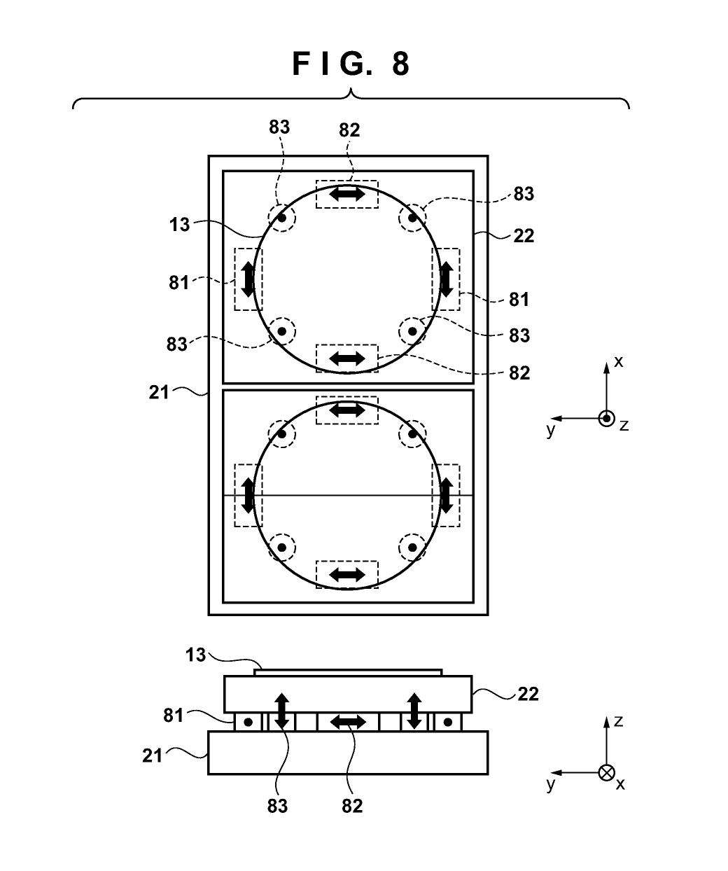

A lithography apparatus according to the sixth embodiment will now be described with reference to FIG. 7. In this embodiment, a substrate conveyance unit 70 is arranged outside a vacuum chamber 11. The substrate conveyance unit 70 is a unit for loading or unloading substrates 13 to or from the vacuum chamber 11. The substrate conveyance unit 70 has substrate conveyance hands 71 for holding and conveying the substrates 13. The substrate conveyance hands 71 are movable in a direction H perpendicular to the arrayed direction of column units (that is, the arrayed direction of the substrates) when conveying the substrates. This makes it possible to minimize the moving distances of stages 14 and the substrate conveyance hands 71, thereby improving footprint efficiency.

### Seventh Embodiment

A lithography apparatus according to the seventh embodiment will now be described with reference to FIG. 8. In this embodiment, a fine moving stage 22 mounted for each substrate on a coarse moving stage 21 has a mechanism which positions with at least one degree of freedom. Since the plurality of substrates are processed in the present invention, a substrate holding step is required for each substrate. Therefore, positions x and y, and an angle θz about a z-axis of each substrate change between the substrates depending on the precision of a substrate conveyance hand. When errors of these x, y, and θz exceed the range of beam position control, a fine moving positioning mechanism can correct them. It is particularly desirable to feedback a value which is obtained by a position measurement mechanism configured for each substrate, and to perform position control.

Also, the thickness unevenness and the flatness of the substrate change between the substrates. These can be pattern errors. Hence, it is desirable to have degrees of freedom to correct a position z, and rotation angles θx and θy.

In the example of FIG. 8, two x-direction actuators 81 and two y-direction actuators 82 can move the fine moving stages 22 in the x, y, and θz directions. Furthermore, four z-direction actuators 83 can move the fine moving stages 22 in the z, θx, and θy directions.

### Eighth Embodiment

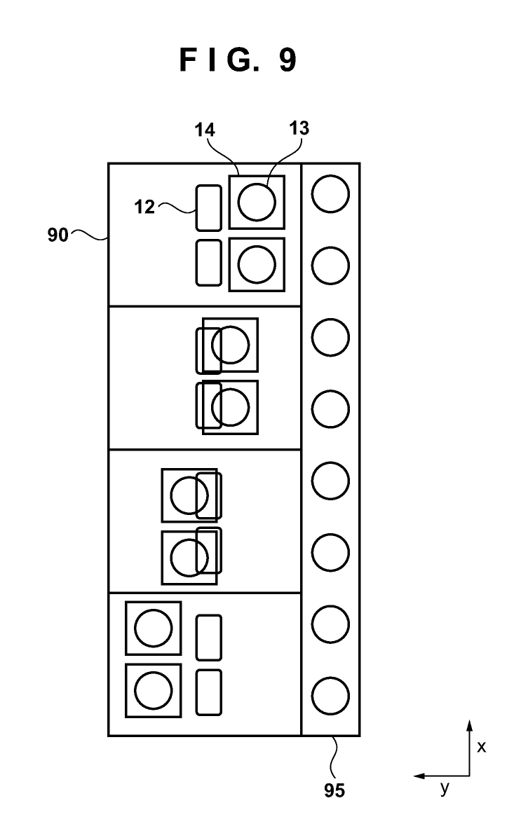

A lithography system according to the eighth embodiment will now be described with reference to FIG. 9. The lithography system according to this embodiment sets a lithography apparatus in any of the above-described embodiments as one cluster, and includes a plurality of such clusters. Also in this arrangement, since a substrate moving distance of each cluster is minimized, a total substrate processing throughput can be improved. In addition, since one cluster processes a plurality of substrates, a space for an actuator required in a stage as well as a redundant space by a chamber wall can be reduced, as compared to a conventional arrangement where one cluster processes one substrate.

In the example of FIG. 9, four clusters 90 are arranged, and one common substrate transport system 95 is arranged among them. Each cluster arranges two substrates in the x direction and can perform writing processing. The common substrate transport system 95 can transport the substrates in the x direction, and load and unload the substrates in the y direction from each cluster.

### Embodiment of Article Manufacturing Method

An article manufacturing method according to an embodiment of the present invention is suitable for manufacturing an article, for example, a microdevice such as a semiconductor device or an element having a microstructure. The article manufacturing method according to this embodiment includes a step of forming a latent image pattern on a photoresist applied to a substrate using the above-described writing apparatus (step of performing writing on a substrate), and a step of developing the substrate on which the latent image pattern has been formed in the preceding step. This manufacturing method further includes other known steps (oxidation, deposition, vapor deposition, doping, planarization, etching, resist peeling, dicing, bonding, packaging, and the like). The article manufacturing method according to this embodiment is advantageous in at least one of the performance, quality, productivity, and production cost of an article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-187646, filed Sep. 10, 2013, which is hereby incorporated by reference herein in its entirety.

What is claimed is:

1. A lithography apparatus which performs writing on a substrate using a charged particle beam, comprising:
a plurality of column units each of which comprises a charged particle optical system;
a plurality of stages each of which is movable while holding the substrate; and
a controller configured to move said plurality of stages in synchronization with each other in a positional relationship corresponding to an arrangement of said plurality of column units, and perform writing on a plurality of substrates held in said plurality of stages simultaneously.

2. The apparatus according to claim 1, further comprising a measurement unit configured to measure positions of said plurality of stages to move said plurality of stages in synchronization with each other.

3. The apparatus according to claim 2, wherein said plurality of column units are arranged so that not more than two column units are arranged on the same line in a planar view.

4. The apparatus according to claim 3, wherein said plurality of column units are three column units, and arranged at respective vertex positions of a triangle in the planar view.

5. The apparatus according to claim 3, wherein said plurality of column units are four column units, and arranged at respective vertex positions of a rectangle in the planar view.

6. The apparatus according to claim 1, wherein each of said plurality of column units includes a plurality of columns each of which comprises the charged particle optical system and is able to irradiate one substrate with a plurality of electron beams, and an arrayed direction of the plurality of columns is parallel to an arrayed direction of said plurality of column units.

7. The apparatus according to claim 1, wherein each of said plurality of column units includes a plurality of columns each of which comprises the charged particle optical system and is able to irradiate one substrate with a plurality of electron beams, and an arrayed direction of the plurality of columns is perpendicular to an arrayed direction of said plurality of column units.

8. The apparatus according to claim 1, further comprising a coarse moving stage,
wherein said plurality of stages are fine moving stages mounted on said coarse moving stage.

9. The apparatus according to claim 8, further comprising a mechanism configured to position the fine moving stages with at least one degree of freedom.

10. The apparatus according to claim 1, further comprising a vacuum chamber configured to contain said plurality of column units and said plurality of stages.

11. The apparatus according to claim 10, further comprising a substrate conveyance unit configured to load or unload the substrate to or from said vacuum chamber,
wherein said substrate conveyance unit includes a substrate conveyance hand which is movable in a direction perpendicular to an arrayed direction of the plurality of substrates.

12. A lithography system comprising a plurality of clusters each of which comprises a lithography apparatus defined in claim 1.

13. A method of manufacturing an article, comprising:
performing writing on a substrate using a lithography apparatus defined in claim 1; and
developing the substrate on which the writing has been performed.
